(19) United States
(12) Patent Application Publication
(10) Pub. No.: US 2002/0079538 A1
(43) Pub. Date: Jun. 27, 2002

(54) Scr-type electrostatic discharge protection circuit

(76) Inventors: Yuan-Mou Su, Hsinchu (TW); Ta-Lee Yu, Hsinchu (TW)

Correspondence Address: FINNEGAN, HENDERSON, FARABOW, GARRETT &, DUNNER LLP, 1300 I STREET, NW, WASHINGTON, DC, 20005, US

(21) Appl. No.: 09/537,566

(22) Filed: Mar. 30, 2000

(51) Int. Cl. H01L 23/62

(52) U.S. Cl. 257/355

(57) ABSTRACT

An SCR-type electrostatic discharge (ESD) protection device includes a PNPN type device disposed between an input pad and ground. The device includes a P-type substrate layer into which an N-type well is formed. A first P+ layer is disposed in the N-type well, and a first N+ region is disposed within the P-type substrate layer for connection to ground. For handling positive transients, the device enters a regenerative mode by avalanching the intermediate PN junction between the N-type well and the P-type substrate layer. A forward-biased diode is provided to handle negative transients. The diode comprises a second P+ region provided in the P-sub layer to bypass the PN junction between the first N+ region and the P-type substrate layer and a second N+ region disposed in the N-type well to bypass the PN junction between the N-type well and the first P+ layer. A tunable resistor is disposed between the input pad and the second N+ region to optimize the performance of the ESD protection device. The resistor improves the turn-on characteristics and lowers the trigger voltage of the device.

### BACKGROUND OF THE INVENTION

1. Field of the Invention

The present invention pertains in general to protection circuitry and, more particularly, to circuitry for providing protection against high-voltage transients due to electrostatic discharge.

2. Description of the Prior Art

Electrostatic discharge (ESD) poses a significant threat of failure to a large number of integrated circuits, especially those circuits employing metal-oxide technology. Electrostatic discharges arise when an external source discharges large transient voltages for a short duration of time onto an input terminal of the integrated circuit. Such discharges commonly occur during circuit fabrication when significant electrostatic charge developed in the human body discharges while handling the integrated circuit device.

Devices fabricated using metal oxide silicon (MOS) technology are especially susceptible to damage from ESD. These devices have only a very small amount of series resistance between the input pad and the actual active circuitry on the device. This small series resistance allows large voltage transients resulting in large currents over a short period of time to pass through the active circuitry. Frequently these voltage transients cause serious damage to the active circuitry of the device.

Damage to integrated circuits caused by ESD can be costly yet can be avoided by using circuitry designed to protect against the effects of ESD. Because integrated circuit devices are particularly susceptible to ESD damage during circuit fabrication, there is a significant probability that damage to a single integrated circuit could render an entire set of electronics inoperative. The required repairs to the fully manufactured devices are often tedious and expensive. These repairs, though, can be avoided simply by including a mechanism for dissipation of the damaging ESD within the integrated circuits.

For devices using CMOS technology, the semiconductor controlled rectifier (SCR) is an ideal solution for protecting against ESD. The SCR provides an ESD structure by exploiting the parasitic lateral PNPN structure inherent in all CMOS circuits. The SCR latches up at a voltage less than that required to damage the input MOS gate oxide, and it exhibits the beneficial feature that while in its conducting state, the heat generated is distributed uniformly within a large volume. One such SCR structure, referred to as a lateral SCR (LSCR) has been described in U.S. Pat. No. 5,012,317.

Prior art LSCR devices, however, exhibit various problems including high trigger voltage, slow turn-on, and turn-on voltage sensitivity to process variation. Generally, these devices also lack tunability for applications in different I/O applications. The present invention addresses these deficiencies by providing an SCR device with a tunable series resistor at an N-well or P-type substrate connection. The ESD performance of the protection circuit can be optimized by tuning the series resistor to the desired value after the SCR wafer is fabricated.

### SUMMARY OF THE INVENTION

The present invention includes an SCR-type ESD protection device comprising a PNPN type device disposed between an input pad and ground. The device includes a P-type substrate layer into which an N-type well is formed. A first P+ layer is disposed in the N-type well, and a first N+ region is disposed within the P-type substrate layer for connection to ground. For handling positive transients, the device enters a regenerative mode by avalanching the intermediate PN junction between the N-type well and the P-type substrate layer. A forward-biased diode is provided to handle negative transients. The diode comprises a second P+ region provided in the P-sub layer to bypass the PN junction between the first N+ region and the P-type substrate layer. A second N+ region is disposed in the N-type well to bypass the PN junction between the N-type well and the first P+ layer.

In a first embodiment of the present invention, a tunable resistor is disposed between the input pad and the second N+ region to optimize the performance of the ESD protection device. The resistor improves the turn-on characteristics and lowers the trigger voltage of the device. In a second embodiment of the present invention, the tunable resistor is disposed between the second P+ region and ground.

Additional advantages of the invention will be set forth in part in the description which follows, and in part will be obvious from the description, or may be learned by practice of the invention. The advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate the embodiments of the invention and together with the description, serve to explain the principles of the invention.

### BRIEF DESCRIPTION OF THE DRAWINGS

FIG. 1a illustrates a conventional SCR-type ESD protection device.

FIG. 1b illustrates a schematic representation of the conventional SCR-type ESD protection device.

FIG. 2a illustrates a first embodiment of the SCR-type ESD protection device of the present invention.

FIG. 2b illustrates a schematic representation of the SCR-type ESD protection device of the present invention.

FIG. 3 illustrates characteristic I-V curves of the conventional SCR-type ESD protection device as well as for the SCR-type ESD protection device of the present invention.

FIG. 4 illustrates a second embodiment of the SCR-type ESD protection device of the present invention.

### DETAILED DESCRIPTION OF THE INVENTION

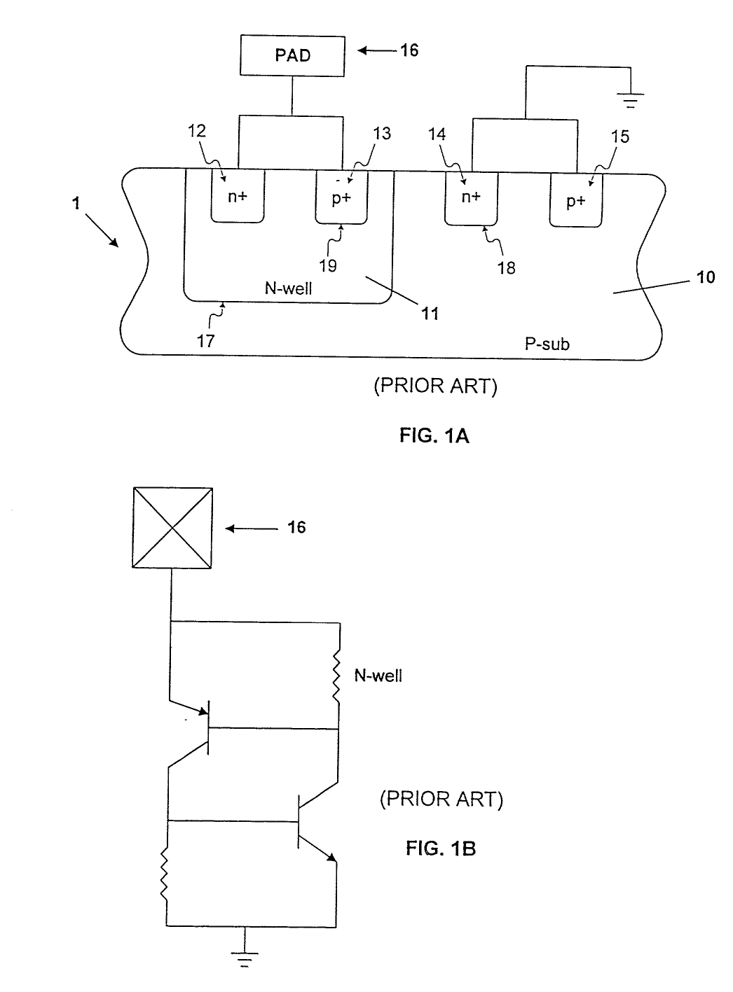

Referring now to FIG. 1A, there is illustrated a cross-sectional view of a prior art ESD protection device which was disclosed in U.S. Pat. No. 5,012,317. The corresponding schematic diagram for this device is depicted by FIG. 1B. In this prior art device, an SCR-type ESD protection device comprising a PNPN type device is disposed between an input pad 16 and ground. The device includes a P-type substrate layer 10 into which an N-type well 11 is formed. A first P+ region or well 13 is disposed in the N-type well 11, and a first N+ region 14 is disposed within the P-type substrate layer for connection to ground. For handling positive transients, the device enters a regenerative mode by avalanching the intermediate PN junction 17 between the N-type well and the P-type substrate layer.

For handling negative transients, a forward-biased diode is provided. This diode comprises a second P+ region 15 provided in the P-sub layer to bypass the PN junction 18 between the first N+ region 14 and the P-type substrate layer 10. A second N+ region 12 of N-type material is disposed in the N-type well 11 to bypass the PN junction 19 between the N-type well 11 and the first P+ layer 13.

In operation, positive transients cause current to flow through P+ region 13 to avalanche the PN junction 17 between N-type well 11 and the P-sub layer 10. Current then flows from the P-sub layer 10 to the N+ region 14 across the PN junction 18 to ground. In the reverse transient mode, current flows from ground through the second P+ region 15 to P-sub layer 10. In this mode, current flows from P-sub layer 10 through PN junction 17 to the N-type well 11 and through N+ region 12 to pad 16.

FIG. 1B depicts a schematic equivalent of the prior art ESD protection device 1 shown in FIG. 1A.

The prior art SCR-type ESD protection device effectively manages to protect integrated circuitry from damage caused by large voltage transients and large currents resulting from electrostatic discharge. Nonetheless, this prior art ESD protection device exhibits several shortcomings. These shortcomings include high trigger voltage, slow turn-on, and turn-on voltage sensitivity to process variation. The prior art ESD protection device also lacks tunability for applications in different I/O applications. The present invention addresses these deficiencies by providing an SCR device with a tunable series resistor at an N-well or P-type substrate connection, described as follows.

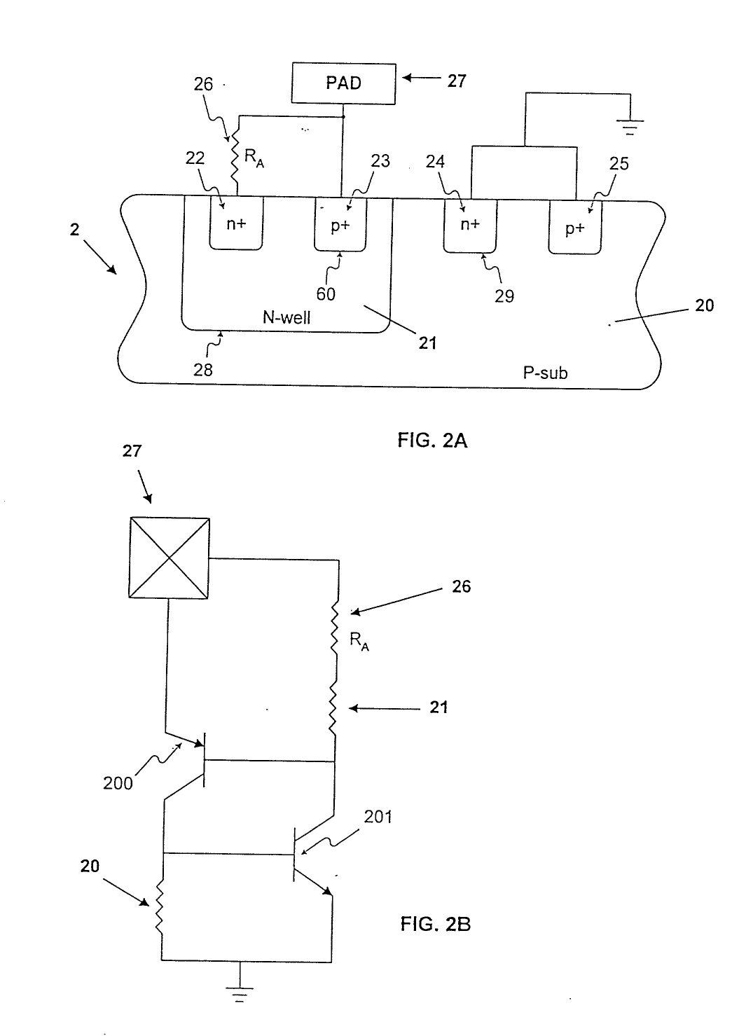

Illustrated in FIG. 2A is a cross-sectional view of an ESD protection device 2 according to the first embodiment of the present invention. The ESD protection device of the first embodiment is an SCR-type device comprising a PNPN structure disposed between an input pad 27 and ground. The device includes an N-type well 21 formed within a P-type substrate layer 20. A first P+ layer 23 is disposed in the N-type well 21, and a first N+ region 24 is disposed within the P-type substrate layer 20 for connection to ground. The PNPN structure provided by the first P+ layer 23, the N-type well 21, the P-type substrate layer 20, and the first N+ region 24 handles positive transients by entering a regenerative mode. The device enters this mode when positive transients cause current to flow through P+ region 23 to avalanche the PN junction 28 between N-type well 21 and the P-sub layer 20. Current then flows from the P-sub layer 20 to the N+ region 24 across the PN junction 29 to ground.

Similar to the prior art device of FIG. 1A, negative transients are handled by a forward-biased diode provided in the ESD protection circuit. This diode comprises a second P+ region 25 provided in the P-sub layer to bypass the PN junction 29 between the first N+ region 24 and the P-type substrate layer 20. A second N+ region 22 of N-type material is disposed in the N-type well 21 to bypass the PN junction 60 between the N-type well 21 and the first P+ layer 23. In the reverse transient mode, current flows from ground through the second P+ region 25 to P-sub layer 20. In this mode, current flows from P-sub layer 20 through PN junction 28 to the N-type well 21 and through N+ region 22 to pad 27.

The ESD protection circuit of the present invention, differs from the device of the prior art by the addition of a tunable, series resistor 26 connected between the pad 27 and the second N+ region 22. In positive transient mode, when PN junction 28 enters breakdown, many electron and hole pairs are generated. The electron current flows to N+ region 22 through series resistor 26. Simultaneously, the hole current flows to the second P+ region 25 through R_{P-sub} resistance. The electron and hole currents activate the NPN and PNP bipolar transistors by forwarding the base-emitter junctions of the NPN and PNP transistors. Series resistor 26 decreases the time required to forward the junction between the P+ region 23 and the N-well. As a result, the PNP transistor can be turned on much more quickly than the devices of the prior art. Further, the device of the present invention exhibits superior ESD performance with respect to the prior art devices.

Series resistor 26 provides the ESD protection circuit of the present invention with several advantages not realized by the prior art devices. As a result of this resistor 26, the ESD device exhibits a low trigger voltage. In an extreme case, for example, the series resistor 26 is large enough such that the electrical path between pad 27 and N+ region 22 is considered to be open. The open base breakdown voltage, BV_{CEO}, of the PNP transistor is represented by the following relationship:

$${BV}_{CEO} = \frac{{BV}_{CBO}}{{( {β}_{o} )}^{\frac{1}{n}}}$$

where βₒ is the common emitter current gain at low collector biases where the multiplication factor is unity. As an example, if the common emitter current gain is 100, then the open base breakdown voltage will be only about one-third of the open emitter breakdown voltage. Thus, in the invention, an increase in the resistance of R_{A}, series resistor 26, subsequently reduces the breakdown voltage. As a quantitative example, in a typical CMOS 0.5 μm process, the BV_{CBO}, or the breakdown voltage of the N-well and P-sub regions, may be about 30˜50 V. The β current gain of the NPN transistor may be 20˜150, and the value of n may be about 1˜2.

Series resistor 26 also decreases the time required to turn on the SCR device. Because the resistor 26 effectively reduces the trigger voltage, less current is required to trigger the SCR to an “ON” mode. Thus, the SCR device of the present invention has faster turn-on characteristics than the conventional LSCR device of the prior art. This advantage is especially useful for applications of CDM-ESD (charged-device-model-ESD). Because CDM-ESD has a faster waveform than ordinary electrostatic energy, prior art SCR devices often are not able to enter the “ON” mode to protect against the CDM-ESD. Often this type of discharge causes damage to circuit components before the conventional SCR devices are activated. As a result of its lower trigger voltage and faster turn-on time, the SCR of the present invention, however, more effectively protects against fast waveforms such as CDM-ESD.

A further advantage that the series resistor 26 provides to the ESD protection circuit of the present invention stems from its tunability. Series resistor 26 is designed to provide a tunable resistance that can be modified after the wafer, on which the ESD protection circuit resides, is made. Thus, according to the desired level of trigger voltage, turn-on speed, and ESD performance, the resistor 26 can be trimmed to provide the desired characteristics of the ESD protection circuit. The resistor 26 can be tuned by any of several different conventional methods for varying the resistance value of a resistor. These methods include using a laser, such as that provided by the commercial FA tool-laser cutter or a focused ion beam (FIB). These methods can be used to tune the resistance value of the resistor 26 after all other processes for fabricating the integrated circuit have been completed.

FIG. 2B shows the schematic corresponding to the device of the first embodiment of the present invention, as depicted in FIG. 2A. As shown in FIG. 2B, the resistor 26 is connected in series with the resistance provided by the N-well 21. Transistor 200 is formed by the PNP junction formed by P+ region 23, N-well 21, and P-sub layer 20. Transistor 201 is formed by the NPN junction of N+ region 22, N-well 21, P-sub 20, and N+ region 24. N-well region 21 and P-sub layer 20 are illustrated in FIG. 2B by the representative resistance components which they create.

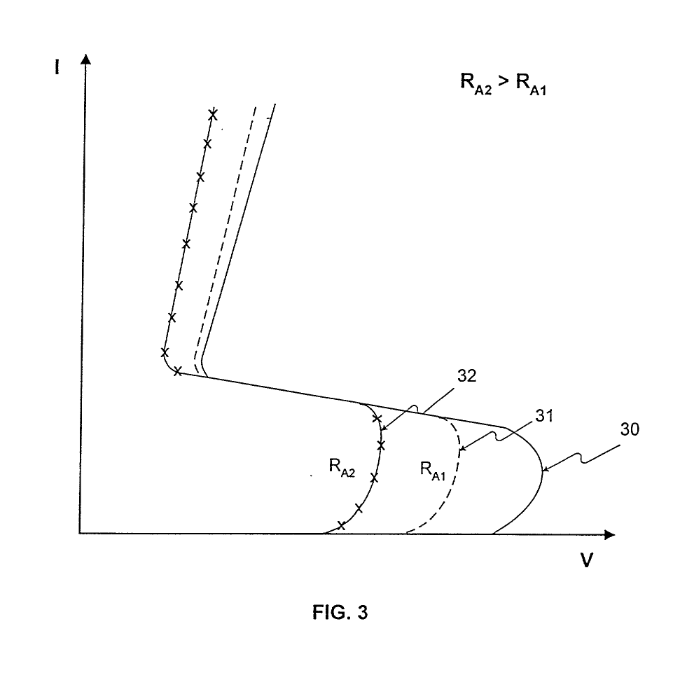

FIG. 3 illustrates characteristic I-V curves of the SCR-type ESD protection device of the present invention in comparison to the typical I-V performance of the conventional SCR-type ESD protection device. Curve 30 represents an I-V plot of the conventional SCR-type ESD device without the series resistor 26. Curves 31 and 32 represent I-V plots of the ESD protection circuit of the present invention each with a series resistor 26 designated by RA₁, and RA₂, respectively, where the resistance of RA₂ is greater than RA₁. As shown in FIG. 3, the trigger voltage level for the operation of the ESD protection circuit is reduced as the resistance value of the series resistor 26 is increased.

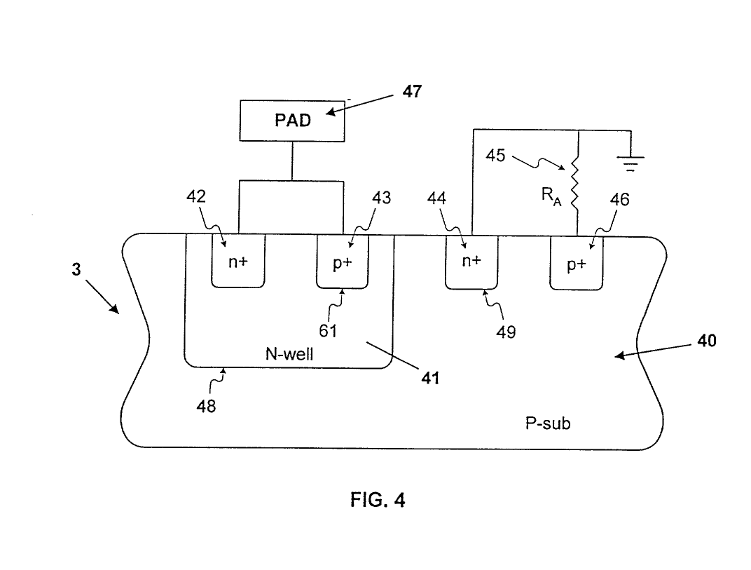

Illustrated in FIG. 4 is a cross-sectional view of an ESD protection device 3 according to the second embodiment of the present invention. Similar to the ESD protection device of the first embodiment shown in FIG. 2A, the second embodiment of the present invention includes an SCR-type device comprising a PNPN structure disposed between an input pad 47 and ground. The device includes an N-type well 41 formed within a P-type substrate layer 40. A first P+ region 43 is disposed in the N-type well 41, and a first N+ region 44 is disposed within the P-type substrate layer 40 for connection to ground. The PNPN structure provided by the first P+ region 43, the N-type well 41, the P-type substrate layer 40, and the first N+ region 44 handles positive transients by entering a regenerative mode. The device enters this mode when positive transients cause current to flow through the P+ region 43 to avalanche the PN junction 48 between N-type well 41 and the P-sub layer 40. Current then flows from the P-sub layer 40 to the N+ region 44 across the PN junction 49 formed between these regions and then to ground.

Also similar to the device of FIG. 2A, negative transients are handled by a forward-biased diode provided in the ESD protection circuit. This diode comprises a second P+ region 46 provided in the P-sub layer to bypass the PN junction 49 between the first N+ region 44 and the P-type substrate layer 40. A second N+ region 42 of N-type material is disposed in the N-type well 41 to bypass the PN junction 61 between the N-type well 41 and the first P+ layer 43. In the reverse transient mode, current flows from ground through the second P+region 46 to P-sub layer 40. In this mode, current flows from P-sub layer 40 through PN junction 48 to the N-type well 41 and through N+ region 42 to pad 47.

In the second embodiment, the series resistor 45 is disposed between the second P+ region 46 and ground. In this embodiment, the resistance R_{P-sub} is modified as opposed to the modification of R_{N-well} as in the first embodiment.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. An electrostatic discharge protection device, disposed between a node and a reference potential, comprising:
a first region of lightly doped semiconductor material of a first conductivity type, wherein said first region forms a body having an upper face;
a second region of lightly doped semiconductor material of a second conductivity type disposed within said first region at said upper face;
a third region of heavily doped semiconductor material of the first conductivity type disposed within said second region at said upper face, wherein said third region is electrically connected to said node;
a fourth region of heavily doped semiconductor material of the second conductivity type disposed within said first region at said upper face, wherein said fourth region is electrically connected to said reference potential;
a fifth region of heavily doped semiconductor material of the second conductivity type disposed within said second region at said upper face;
a sixth region of heavily doped semiconductor material of the first conductivity type disposed within said first region at said upper face, wherein said sixth region is electrically connected to said reference potential; and
a resistor having a first terminal connected to said node and a second terminal connected to said fifth region.

2. The electrostatic discharge protection device of claim 1, wherein said first conductivity type is P-type and said second conductivity type is N-type.

3. The electrostatic discharge protection device of claim 1, wherein said resistor is tunable.

4. The electrostatic discharge protection device of claim 1, wherein said resistor is formed using a focused ion beam.

5. The electrostatic discharge protection device of claim 1, wherein said resistor is formed using a laser.

6. The electrostatic discharge protection device of claim 1, wherein said node is a pad of an integrated circuit, and said reference potential is ground.

7. An electrostatic discharge protection device, disposed between a node reference potential, comprising:
a first region of lightly doped semiconductor material of a first conductivity type, wherein said first region forms a body having an upper face;
a second region of lightly doped semiconductor material of a second conductivity type disposed within said first region at said upper face;
a third region of heavily doped semiconductor material of the first conductivity type disposed within said second region at said upper face, wherein said third region is electrically connected to said node;
a fourth region of heavily doped semiconductor material of the second conductivity type disposed within said first region at said upper face, wherein said fourth region is electrically connected to said reference potential;
a fifth region of heavily doped semiconductor material of the second conductivity type disposed within said second region at said upper face;
a sixth region of heavily doped semiconductor material of the first conductivity type disposed within said first region at said upper face; and
a resistor having a first terminal connected to said reference potential and a second terminal connected to said sixth region.

8. The electrostatic discharge protection device of claim 7, wherein said first conductivity type is P-type and said second conductivity type is N-type.

9. The electrostatic discharge protection device of claim 7, wherein said resistor is tunable.

10. The electrostatic discharge protection device of claim 7, wherein said resistor is formed using a focused ion beam.

11. The electrostatic discharge protection device of claim 7, wherein said resistor is formed using a laser.

12. The electrostatic discharge protection device of claim 7, wherein said node is a pad of an integrated circuit, and said reference potential is ground.

13. An electrostatic discharge protection device, disposed between a node and a reference potential, comprising:
a PNPN type device disposed between an input pad and ground, wherein said PNPN type device comprises a P-type substrate layer, an N-type well, a P+ region, a first N+ region disposed adjacent to said P+ region, and a second N+ region connected to said reference potential; and
a resistor having a first terminal connected to said node and a second terminal connected to said first N+ region.

14. The electrostatic discharge protection device of claim 13, wherein said resistor is tunable.

15. The electrostatic discharge protection device of claim 13, wherein said resistor is formed using a focused ion beam.

16. The electrostatic discharge protection device of claim 13, wherein said resistor is formed using a laser.

17. The electrostatic discharge protection device of claim 13, wherein said node is a pad of an integrated circuit, and said reference potential is ground.
